(19) United States
(12) Patent Application Publication
(10) Pub. No.: US 2023/0305381 A1
(43) Pub. Date: Sep. 28, 2023

(54) EUV PHOTO MASKS AND MANUFACTURING METHOD THEREOF

(71) Applicant: TAIWAN SEMICONDUCTOR MANUFACTURING COMPANY, LTD., Hsinchu (TW)

(72) Inventors: Wei-Shuo SU, Hsinchu City (TW); Yu-Tse LAI, Zhubei City (TW); Sheng-Min WANG, New Taipei City (TW); Ken-Hsien HSIEH, Taipei City (TW); Chieh-Jen CHENG, Hsinchu City (TW); Ya Hui CHANG, Hsinchu City (TW)

(21) Appl. No.: 17/833,823

(22) Filed: Jun. 6, 2022

Related U.S. Application Data
(60) Provisional application No. 63/322,537, filed on Mar. 22, 2022.

(51) Int. Cl. G03F 1/24; G03F 1/42

(52) U.S. Cl. CPC G03F 1/24; G03F 1/42

(57) ABSTRACT

A photo mask for an extreme ultraviolet (EUV) lithography includes a mask alignment mark for aligning the photo mask to an EUV lithography tool, and sub-resolution assist patterns disposed around the mask alignment mark. A dimension of the sub-resolution assist patterns is in a range from 10 nm to 50 nm.

### RELATED APPLICATION

This application claims priority to U.S. Provisional Pat. Application No. 63/322,537 filed Mar. 22, 2022, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). The photo mask is an important component in photolithography operations. It is critical to fabricate EUV photo masks having a high contrast with a high reflectivity part and a high absorption part.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show an EUV reflective photo mask according to an embodiment of the present disclosure.

FIG. 2A is a plan view or a layout view of an EUV photo mask according to an embodiment of the present disclosure. FIG. 2B shows a plan view of a mask alignment mark area.

FIG. 3A shows a plan view of a mask alignment mark area according to an embodiment of the present disclosure. FIGS. 3B and 3C shows plan views of mask alignment marks according to embodiments of the present disclosure.

FIG. 4 shows simulation or calculation results showing background intensity suppression by sub-resolution patterns according to embodiments of the present disclosure.

FIG. 5A is a plan view (layout view) and FIGS. 5B, 5C, 5D and 5E show cross sectional views corresponding to line X1, line X2, line Y1 and line Y2 of FIG. 5A, respectively, of an EUV photo mask according to an embodiment of the present disclosure.

FIG. 6A is a plan view (layout view) and FIGS. 6B, 6C, 6D and 6E show cross sectional views corresponding to line X1, line X2, line Y1 and line Y2 of FIG. 6A, respectively, of an EUV photo mask according to an embodiment of the present disclosure. FIGS. 6F, 6G, 6H and 6I show cross sectional views corresponding to line X1, line X2, line Y1 and line Y2 of FIG. 6A, respectively, of an EUV photo mask according to an embodiment of the present disclosure. FIGS. 6J and 6K show views an EUV photo mask according to an embodiment of the present disclosure.

FIGS. 7A, 7B, 7C and 7D schematically illustrate a method of fabricating an EUV photo mask according to an embodiment of the present disclosure.

FIGS. 8A and 8B shows plan views of mask alignment marks according to embodiments of the present disclosure.

FIG. 9 illustrate various sub-resolution assist features according to embodiments of the present disclosure.

FIGS. 10A and 10B show a photo mask data generating apparatus according to an embodiment of the present disclosure.

FIG. 11A shows a flowchart of a method making a semiconductor device, and FIGS. 11B, 11C, 11D and 11E show a sequential manufacturing operation of a method of making a semiconductor device in accordance with embodiments of present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of′ may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Materials, configurations, processes and/or dimensions as explained with respect to one embodiment may be employed in other embodiments and detailed description thereof may be omitted. In the present disclosure, a reticle, a photo mask, or a mask are interchangeable used.

Embodiments of the present disclosure provide a method of manufacturing an EUV photo mask. More specifically, the present disclosure is directed to a structure of a reticle (mask) alignment mark, such as a transmission image sensor (TIS) alignment mark. The TIS alignment system is for aligning the photo mask to the mask stage of an EUV lithography tool (EUV scanner), and is not used for alignment between the photo mask and the patterned wafer.

EUV lithography (EUVL) employs scanners using light in the extreme ultraviolet (EUV) region, having a wavelength of about 1 nm to about 100 nm, for example, 13.5 nm. The mask is a critical component of an EUVL system. Because the optical materials are not transparent to EUV radiation, EUV photo masks are reflective masks. Circuit patterns are formed in an absorber layer disposed over the reflective structure.

A TIS alignment system uses one or more TIS alignment marks formed on an EUV photo mask. EUV light is directed to the TIS alignment marks, and the reflected light is detected by a TIS sensor disposed on a wafer stage. In some embodiments, two EUV beams are applied from different directions so that a fringe pattern caused by interference is observed by the TIS sensor. It is generally required that a TIS alignment mark generate a high contrast reflective patten (signal). The present disclosure provides an EUV reflective photo mask having a high contrast mask alignment mark.

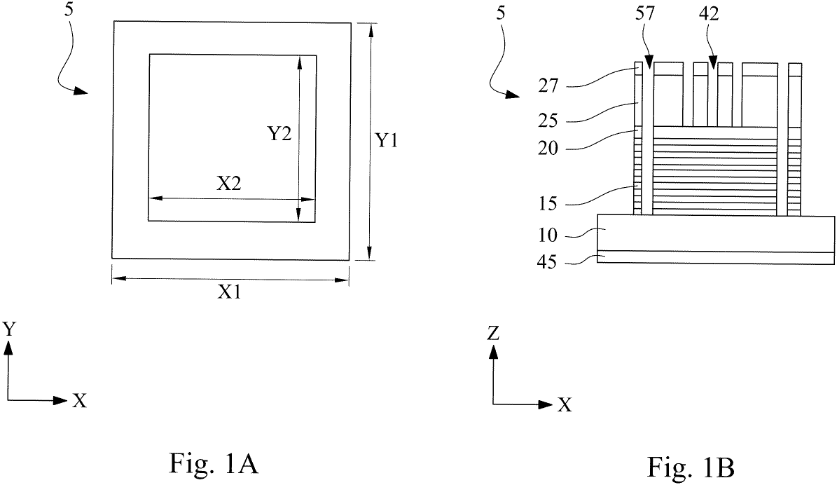

FIGS. 1A and 1B show an EUV reflective photo mask according to an embodiment of the present disclosure. FIG. 1A is a plan view (viewed from the top) and FIG. 1B is a cross sectional view.

In some embodiments, the EUV photo mask 5 includes a substrate 10, a multilayer Mo/Si stack 15 of multiple alternating layers of silicon and molybdenum, a capping layer 20 and an absorber layer 25. In some embodiments, an antireflective layer 27 is optionally disposed over the absorber layer 25. Further, a backside conductive layer 45 is formed on the backside of the substrate 10, as shown in FIG. 1B.

The substrate 10 is formed of a low thermal expansion material in some embodiments. In some embodiments, the substrate 10 is a low thermal expansion glass or quartz, such as fused silica or fused quartz. In some embodiments, the low thermal expansion glass substrate transmits light at visible wavelengths, a portion of the infrared wavelengths near the visible spectrum (near infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size X1 × Y1 of the substrate 10 is about 152 mm × about 152 mm having a thickness of about 20 mm. In other embodiments, the size of the substrate 10 is smaller than 152 mm × 152 mm and equal to or greater than 148 mm × 148 mm. The shape of the substrate 10 is square or rectangular in some embodiments.

In some embodiments, the functional layers above the substrate (the multilayer Mo/Si stack 15, the capping layer 20, the absorber layer 25 and the cover layer 27 have a smaller width than the substrate 10. In some embodiments, the size X2 × Y2 of the functional layers is in a range from about 138 mm × 138 mm to 142 mm × 142 mm. The shape of the functional layers is square or rectangular in some embodiments. In other embodiments, the absorber layer 25 and the cover layer 27 have a smaller size in the range from about 138 mm × 138 mm to about 142 mm × 142 mm than the substrate 10, the multilayer Mo/Si stack 15 and the capping layer 20. The smaller size of one or more of the functional layers can be formed by using a frame shaped cover having an opening in a range from about 138 mm × 138 mm to about 142 mm × 142 mm, when forming the respective layers by, for example, sputtering. In other embodiments, all of the layers above the substrate 10 have the same size as the substrate 10.

In some embodiments, the Mo/Si multilayer stack 15 includes from about 30 to 60 alternating pairs of silicon and molybdenum layers. In certain embodiments, the number of pairs is about 40 to about 50. In some embodiments, the reflectivity is higher than about 70% for the wavelengths of interest e.g., 13.5 nm. In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm, and the thickness of each molybdenum layer is about 3 nm. In some embodiments, the bottommost layer of the multilayer stack 15 is a Si layer or a Mo layer.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for the wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer stack 15 to prevent oxidation of the multilayer stack 15 in some embodiments. In some embodiments, the capping layer 20 is made of elemental ruthenium (more than 99% Ru, not a Ru compound), a ruthenium alloy (e.g., RuNb, RuZr, RuZrN, RuRh, RuNbN, RuRhN, RuV, RuVN, RuIr, RuTi, RuB, RuP, RuOs, RuPd RuPt or RuRe) or a ruthenium based oxide (e.g., RuO₂, RuNbO, RiVO or RuON), having a thickness of from about 2 nm to about 10 nm. In some embodiments, the capping layer 20 is a ruthenium compound RuₓM₁₋ₓ, where M is one or more of Nb, Ir, Rh, Zr, Ti, B, P, V, Os, Pd, Pt or Re, and x is more than zero and equal to or less than about 0.5

In certain embodiments, the thickness of the capping layer 20 is from about 2 nm to about 5 nm. In some embodiments, the capping layer 20 has a thickness of 3.5 nm ± 10%. In some embodiments, the capping layer 20 is formed by chemical vapor deposition, plasma-enhanced chemical vapor deposition, atomic layer deposition, physical vapor deposition (e.g., sputtering), or any other suitable film forming method. In other embodiments, a Si layer is used as the capping layer 20. One or more layers are disposed between the capping layer and the multilayer 15 as set forth below in some embodiments.

In some embodiments, the capping layer 20 includes two or more layers of different materials. In some embodiments, the capping layer 20 includes two or more layers of different Ru based materials. In some embodiments, the capping layer 20 includes two layers, a lower layer and an upper layer, and the upper layer has a higher carbon absorption resistance than the lower layer, and the lower layer has a higher etching resistance during the absorber etching. In certain embodiments, the capping layer 20 includes a RuNb based layer (RuNb or RuNbN) disposed on a RuRh based layer (RuRh or RuRhN).

The absorber layer 25 is disposed over the capping layer 20. The absorber layer 25 includes one or more layers of a high EUV absorption. In some embodiments, the absorber layer 25 is Ta based material. In some embodiments, the absorber layer 25 is made of TaN, TaO, TaB, TaBO or TaBN. In some embodiments, the absorber layer 25 has a multilayered structure of TaN, TaO, TaB, TaBO or TaBN. In other embodiments, the absorber layer 25 includes a Cr based material, such as CrN, CrBN, CrO and/or CrON. In some embodiments, the absorber layer 25 has a multilayered structure of Cr, CrO or CrON. In some embodiments, the absorber layer is Ir or an Ir based material, such as, IrRu, IrPt, IrN, IrAl, IrSi or IrTi. In some embodiments, the absorber layer is a Ru based material, such as, IrRu, RuPt, RuN, RuAl, RuSi or RuTi, or a Pt based material, PtIr, RuPt, PtN, PtAl, PtSi or PtTi. In other embodiments, the absorber layer includes an Os based material, a Pd based material, or a Re based material. In some embodiments of the present disclosure, an X based material means that an amount of X is equal to or more than 50 atomic%. In other embodiments, the absorber layer material is represented by AₓB_{y}, where A and B are each one or more of Ir, Pt, Ru, Cr, Ta, Os, Pd, Al or Re, and x:y is from about 0.25:1 to about 4:1. In some embodiments, x is different from y (smaller or larger). In some embodiments, the absorber layer further includes one or more of Si, B, or N in an amount of more than zero to about 10 atomic%.

In some embodiments, the thickness of the absorber layer 25 ranges from about 10 nm to about 100 nm, and ranges from about 25 nm to about 75 nm in other embodiments. In some embodiments, the absorber layer 25 is formed by chemical vapor deposition, plasma-enhanced chemical vapor deposition, atomic layer deposition, physical vapor deposition, or any other suitable film forming method. One or more layers are disposed between the capping layer 20 and the absorber layer 25 as set forth below in some embodiments.

In some embodiments, a cover or antireflective layer 27 is disposed over the absorber layer 25. In some embodiments, the cover layer 27 includes a Ta based material, such as TaB, TaO or TaBO, silicon, a silicon based compound (e.g., silicon oxide, SiN, SiON or MoSi), ruthenium, or a ruthenium based compound (Ru or RuB). In certain embodiments, the cover layer 27 is made of tantalum oxide (Ta₂O₅ or non-stoichiometric (e.g., oxygen deficient) tantalum oxide), and has a thickness of from about 2 nm to about 20 nm. In other embodiments, a TaBO layer having a thickness in a range from about 2 nm to about 20 nm is used as the cover layer. In some embodiments, the thickness of the cover layer 27 is from about 2 nm to about 5 nm. In some embodiments, the cover layer 27 is formed by chemical vapor deposition, plasma-enhanced chemical vapor deposition, atomic layer deposition, physical vapor deposition, or any other suitable film forming method.

In some embodiments, the backside conductive layer 45 is disposed on a second main surface of the substrate 10 opposing the first main surface of the substrate 10 on which the Mo/Si multilayer stack 15 is formed. In some embodiments, the backside conductive layer 45 is made of TaB (tantalum boride) or other Ta based conductive material. In some embodiments, the tantalum boride is crystalline. The crystalline tantalum boride includes TaB, Ta₅B₆, Ta₃B₄ and TaB₂. In other embodiments, the tantalum boride is poly crystalline or amorphous. In other embodiments, the backside conductive layer 45 is made of a Cr based conductive material (CrN or CrON). In some embodiments, the sheet resistance of the backside conductive layer 45 is equal to or smaller than 20 Ω /_{□}. In certain embodiments, the sheet resistance of the backside conductive layer 45 is equal to or more than 0.1 Ω /_{□}. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm. In some embodiments, the flatness of the backside conductive layer 45 is more than 1 nm. A thickness of the backside conductive layer 45 is in a range from about 50 nm to about 400 nm in some embodiments. In other embodiments, the backside conductive layer 45 has a thickness of about 50 nm to about 100 nm. In certain embodiments, the thickness is in a range from about 65 nm to about 75 nm. In some embodiments, the backside conductive layer 45 is formed by atmospheric chemical vapor deposition (CVD), low pressure CVD, plasma-enhanced CVD, laser-enhanced CVD, atomic layer deposition (ALD), molecular beam epitaxy (MBE), physical vapor deposition including thermal deposition, pulsed laser deposition, electron-beam evaporation, ion beam assisted evaporation and sputtering, or any other suitable film forming method. In cases of CVD, source gases include TaCls and BCl₃ in some embodiments.

As shown in FIG. 1B, the EUV photo mask 5 include a circuit pattern 42 in the circuit pattern area and a black border 57 surrounding the circuit pattern area.

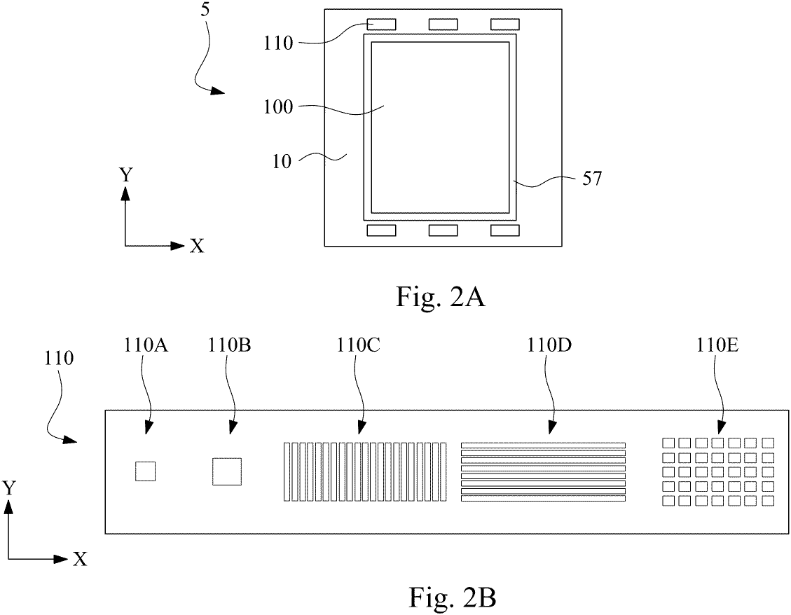

FIG. 2A is a plan view or a layout view of an EUV photo mask according to an embodiment of the present disclosure.

Similar to FIGS. 1A and 1B, an EUV photo mask includes a substrate 10 and a circuit area 100. In some embodiments, multiple chip patterns are disposed in the circuit area 100. The EUV photo mask further includes one or more mask alignment mark systems 110 as shown in FIG. 2A.

FIG. 2B shows various mask alignment marks included in one alignment mark system 110. In some embodiments, the alignment mark system 110 include a first coarse alignment mark 110A, a second coarse alignment mark 110B, a first fine alignment mark for the X direction 110C, a first fine alignment mark for the Y direction 110D and a second fine alignment mark 110E. In some embodiments, the first coarse alignment mark 110A and the second coarse alignment mark 110A are a square pattern. In some embodiments, the first fine alignment marks 110C and 110D are periodical line-and-space patterns having a pitch of about 3000-5000 nm (e.g., 4000 nm) and a line width of about 100-300 nm (e.g., 200 nm). In some embodiments, the second fine alignment mark 110E includes a matrix of small square patterns having a pitch of about 3000-5000 nm (e.g., 4000 nm) and each square pattern has a side length of about 100-300 nm (e.g., 200 nm).

An EUV light for an alignment process applied to the fine alignment marks, respectively, generates a diffraction pattern according to the periodical structure of the fine alignment marks and the diffraction pattern is detected by the TIS sensor. In some embodiments, the mask alignment marks are placed on the photo mask at a region outside the black border pattern, and are not printed on a resist-coated wafer (not projected onto the wafer).

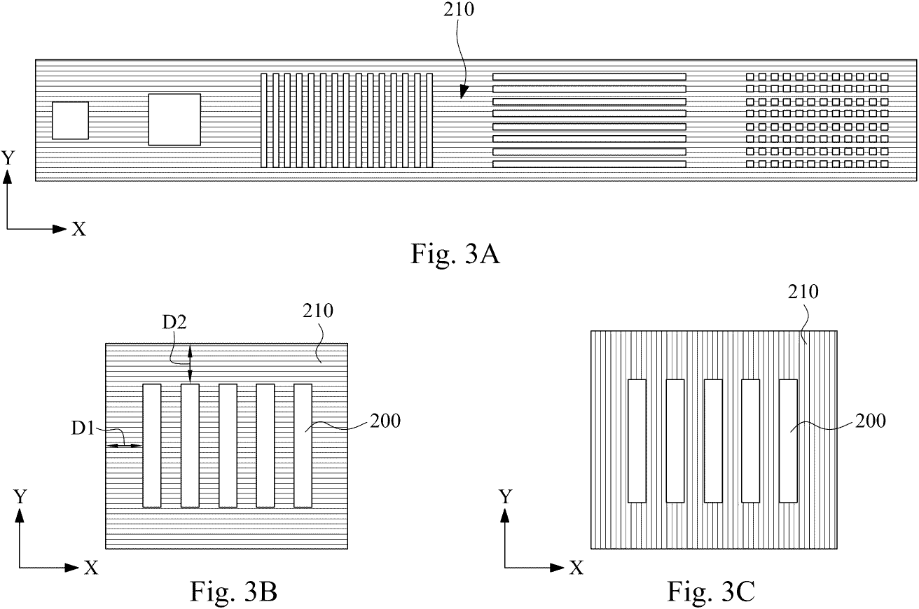

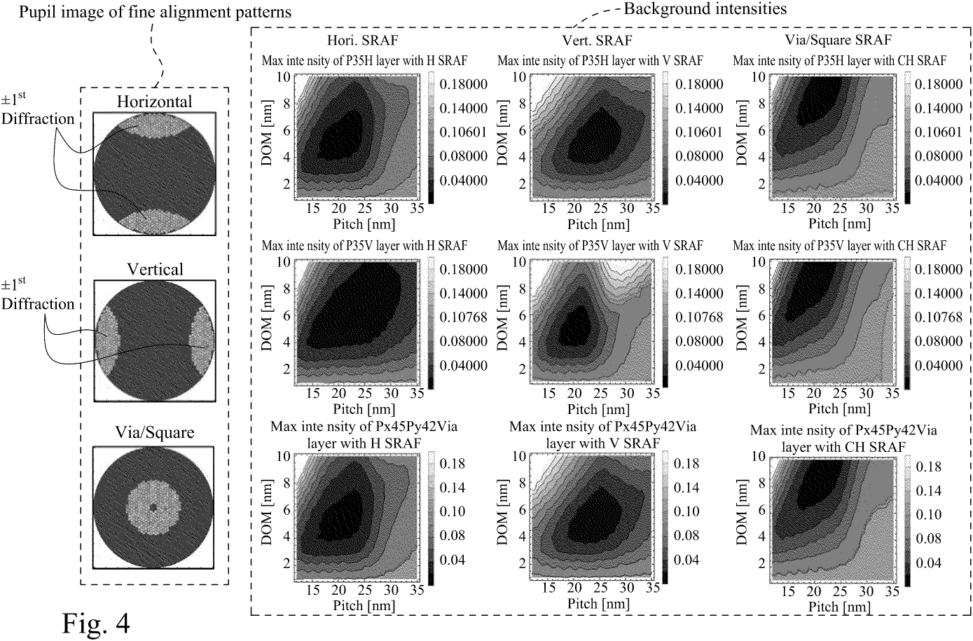

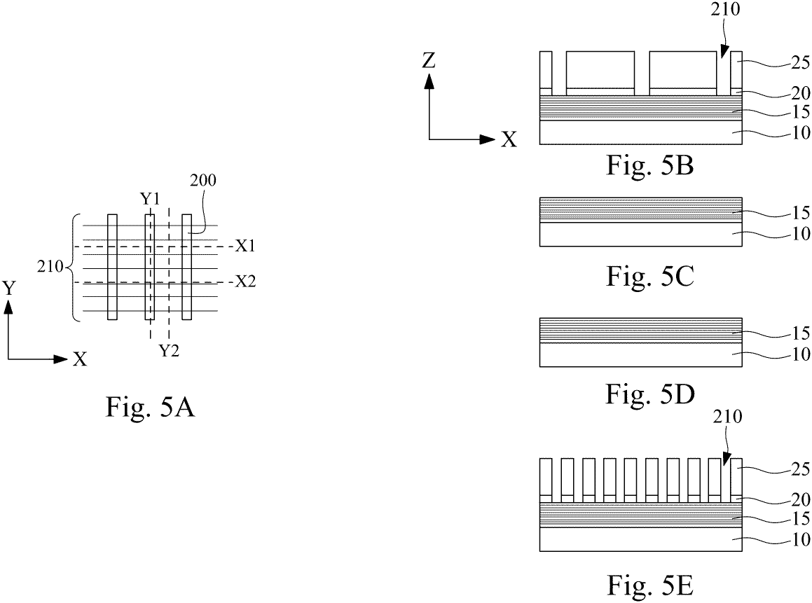

In some embodiments, the EUV photo mask 5 is an attenuated phase shift mask (APSM). In some embodiments of the present disclosure, in order to suppress a background optical signal to increase a signal contract, a plurality of sub-resolution assist features (SRAFs) 210 are placed around the alignment marks, as shown in FIG. 3A. In particular, when the absorber layer 25 of the EUV photo mask includes a low-n and/or low-k EUV absorbing layer having a refractive index n less than about 0.95 (and more than about 0.5) and an absorption coefficient k less than about 0.04 (and more than about 0.005) for the EUV light (e.g., 13.5 nm), the SRAF 210 can effectively improve the signal contrast. In some embodiments, the reflectivity of the absorber layer 25 is equal to or greater than about 5% (and less than about 10%).

In some embodiments, when the photo mask is a 4X mask, the SRAF 210 includes a grating, such as periodical patterns having a pitch equal to or more than about 40 nm and less than about 160 nm, and in a range from about 60 nm to about 120 nm in other embodiments. When the photo mask is a 5X mask, the SRAF 210 includes periodical patterns having a pitch in a range from about 50 nm to about 200 nm, and in a range from about 75 nm to about 150 nm in other embodiments. In other words, the pitch of the periodical patterns on the sensor (on the wafer level) is about 10 nm or more and less than about 40 nm. In some embodiments, the SRAF 210 includes periodical line and space patterns having the aforementioned pitch(es), and the width of the line pattern is in a range from about 10 nm to about 50 nm on the 4X mask, and is in a range from about 20 nm to about 40 nm in other embodiments. In some embodiments, a ratio of the line width to the pitch (aspect ratio) is in a range from about 0.2 to about 0.8.

FIGS. 3B and 3C show SRAF patterns according to various embodiments of the present disclosure. In some embodiments, the first fine alignment mark 110C (or 110D) includes a line-and-space pattern 200 extending in the Y direction and arranged in the X direction and having a width of 50 nm and a pitch of 200 nm. In some embodiments, as shown in FIG. 3B, the SRAF 210 includes line-and-space patterns extending in the X direction and arranged in the Y direction, i.e., perpendicular to the first fine alignment mask patterns 200. In other embodiments, as shown in FIG. 3C, the SRAF 210 includes line-and-space patterns extending in the Y direction and arranged in the X direction, i.e., parallel to the first fine alignment mask patterns 200.

In some embodiments, the SRAF patterns 210 are provided in the area surrounding the TIS alignment marks. In some embodiments, the distance D1 and D2 between the outermost edges of the TIS alignment marks 200 in the X direction and the Y direction to the outer periphery of the SRAF patterns 210 is in a range from about 4000 nm to 40,000 nm on the photo mask.

In FIGS. 2 and 3A-3C, the line or square patterns correspond to a trench, a groove and/or an opening formed in the absorber layer 25 and thus are EUV reflective patterns.

FIG. 4 shows the effects of the SRAF patterns for the TIS alignment marks. FIG. 4 shows pupil images of alignment marks, and the background intensity with SRAF patterns. In some embodiments, the “Horizontal” corresponds to the first fine alignment mark for Y direction 110D, the “Vertical” corresponds to the first fine alignment mark for X direction 110C, and “Via/Square” corresponds to either the coarse alignment marks 110A or 110B. In the background intensity diagrams, the horizontal axis shows a pitch of the SRAF and the vertical axis shows a width of the line pattern of the SRAF, and the darker regions indicate lower background intensities. As shown in FIG. 4, it is possible to effectively suppress the background intensity by adjusting the pitch and/or line width of the SRAF patterns. Thus, the SRAF patterns are background intensity suppression patterns.

FIGS. 5A-5E shows various view of the structure of the fine alignment marks for the TIS mask alignment. FIG. 5A is a plan view (layout view), FIGS. 5B, 5C, 5D and 5E show cross sectional views corresponding to line X1, line X2, line Y1 and line Y2, respectively. As shown in FIGS. 5A-5E, the fine alignment mark includes line patterns 200 as trenches formed in the absorber layer 25 and the capping layer 20, and the SRAF also includes line patterns 210 as trenches formed in the absorber layer 25 and the capping layer 20.

The fine alignment marks with the SRAF pattern can be formed at the same time as the formation (e-beam lithography) of the circuit patterns. In some embodiments, the SRAF pattern is formed before or after the alignment mark patterns are formed. For example, before or after the alignment mark patterns are formed by electron beam lithography and etching operations, another photo resist layer is formed over the photo mask, and then an electron beam lithography or other lithography operations (optical, laser interference, etc.) are performed to form the SRAF patterns.

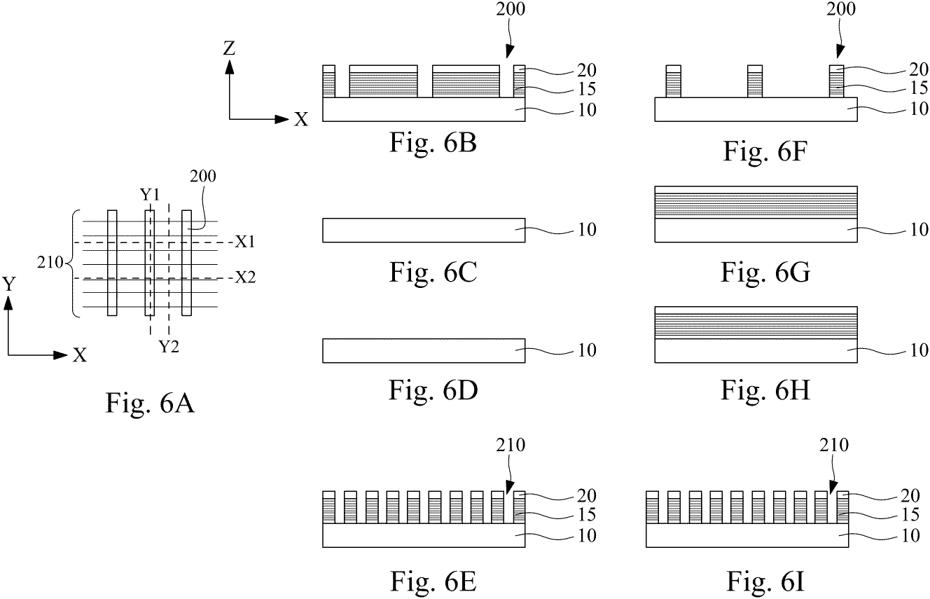

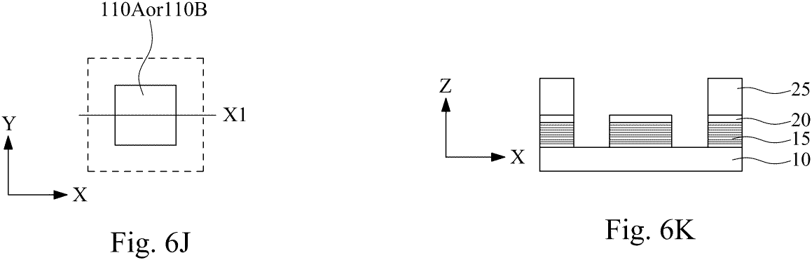

FIGS. 6A-6E shows various view of the structure of the fine alignment marks for the TIS mask alignment. FIG. 6A is a plan view (layout view), FIGS. 6B, 6C, 6D and 6E show cross sectional views corresponding to line X1, line X2, line Y1 and line Y2, respectively. As shown in FIGS. 6A-6E, the fine alignment mark includes line patterns 200 as trenches formed in the capping layer 20 and the multilayer reflective layer 15, and the SRAF also includes line patterns 210 as trenches formed in the capping layer 20 and the multilayer reflective layer 15. As shown in FIGS. 6A-6E, no absorber layer 25 is disposed in the fine alignment marks. In some embodiments, the alignment marks 110A-110E shown in FIG. 2B are formed as non-reflective patterns (substrate) surrounded by reflective patterns of the reflective multilayer 15, as shown in FIGS. 6B-6E. In other embodiments, the alignment marks 110A-110E shown in FIG. 2B are formed as reflective patterns by the reflective multilayer 15 surrounded by openings in which the substrate is exposed, which is further surrounded by an absorber layer, as shown in FIGS. 6F-6I.

In some embodiments, the first and/or second coarse alignment marks 110A, 110B have the structure shown in FIGS. 6J and 6K. FIG. 6K shows a cross sectional view along the line X1 of FIG. 6J. The square pattern of the coarse alignment marks is formed as a reflective pattern of the reflective multilayer 15 and the capping layer 20 surrounded by a non-reflective opening exposing the substrate.

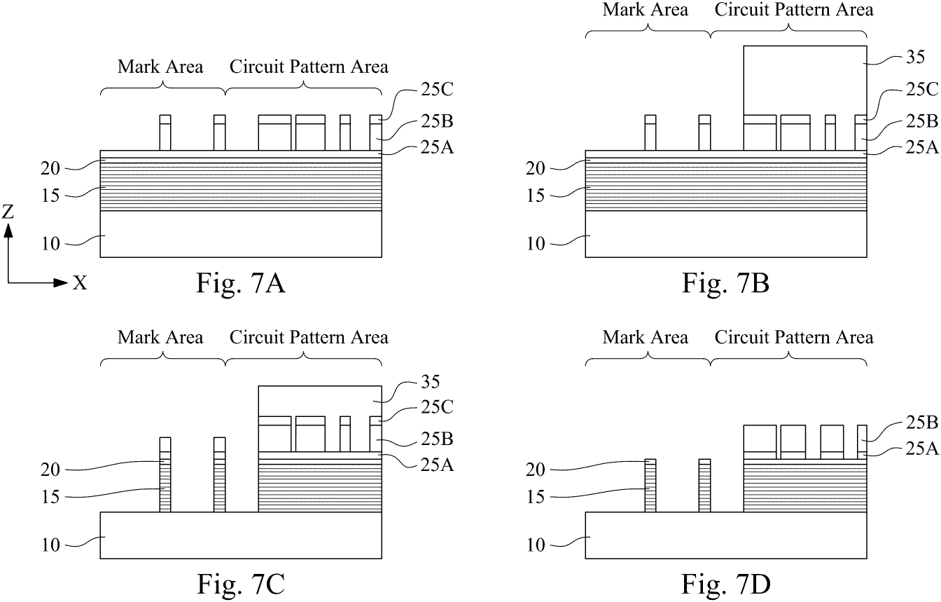

FIGS. 7A-7D show various stages of a sequential manufacturing operation of an EUV photo mask corresponding to FIGS. 6A-6E according to an embodiment of the present disclosure. It is understood that additional operations can be provided before, during, and after processes shown by FIGS. 7A-7D, and some of the operations described below can be replaced or eliminated for additional embodiments of the method. The order of the operations/processes may be interchangeable. Materials, configurations, processes and/or dimensions as explained with respect to the foregoing embodiments may be employed in the following embodiments and detailed description thereof may be omitted.

FIG. 7A shows a cross section view after the circuit pattern is formed in the circuit pattern area. In some embodiments, a first photoresist layer is formed over a hard mask layer of an EUV photo mask blank, and the photoresist layer is selectively exposed to actinic radiation, such as an electron beam. The selectively exposed first photoresist layer is developed to form a pattern in the first photoresist layer. In some embodiments, the electron beam lithography also forms the alignment marks as a resist pattern in the mark area. Next, the pattern in the first photoresist layer is extended into the hard mask layer forming a hard mask pattern, and the first photoresist layer is removed. Then, the hard mask pattern is extended into the absorber layer 25 by etching. In some embodiments, after the etching, the hard mask pattern is removed.

In some embodiments, the absorber layer 25 includes an upper absorber layer 25C, a middle absorber layer 25B and a lower absorber layer 25A. In some embodiments, the upper absorber layer 25C functions as the hard mask pattern. In other embodiments, the upper absorber layer 25C is patterned using the hard mask pattern as an etching mask, and then the middle absorber layer 25B is patterned using the patterned upper absorber layer 25C as an etching mask. In some embodiments, the upper absorber layer 25C and the lower absorber layer 25A are made of tantalum oxide, and the middle absorber layer 24B is made of a low-n and/or low-k EUV absorbing material having a refractive index n less than about 0.95 and an absorption coefficient k less than about 0.04. As shown in FIG. 7A, the etching of the middle absorber layer 25B substantially stops at the lower absorber layer 25A.

Then, as shown in FIG. 7B, the circuit pattern area is covered by a second photo resist layer 35. Next, as shown in FIG. 7C, the lower absorber layer 25A, the capping layer 20 and the reflective multilayer 15 are patterned by one or more etching operations. Then, the middle absorber layer 25B in the mark area is removed. Further, the second photo resist pattern 35 is removed. Then, the upper absorber layer 25C in the circuit area and the mark area and the lower absorber layer 25A in the circuit area are removed by one or more etching operations as shown in FIG. 7D. In some embodiments, as shown in FIG. 7D, the pattern in the circuit area includes trenches (grooves, opening) as a reflective pattern formed in the middle absorber layer 25B made of, for example, the low-k and/or low-n material and the lower absorber layer 25A, and the pattern in the mark area includes a reflective pattern formed by the reflective multilayer 15 and the capping layer 20 surrounded by openings, in the bottoms of which the substrate 10 is exposed. In some embodiments, the alignment mark structure shown in FIG. 7D apply to both the coarse alignment marks 110A and 110B and the fine alignment marks 110C, 110D and 11E. In other embodiments, the alignment mark structure shown in FIG. 7D applies to the coarse alignment marks 110A and 110B, and the structure of the circuit patterns applies to the fine alignment marks 110C, 110D and 11E.

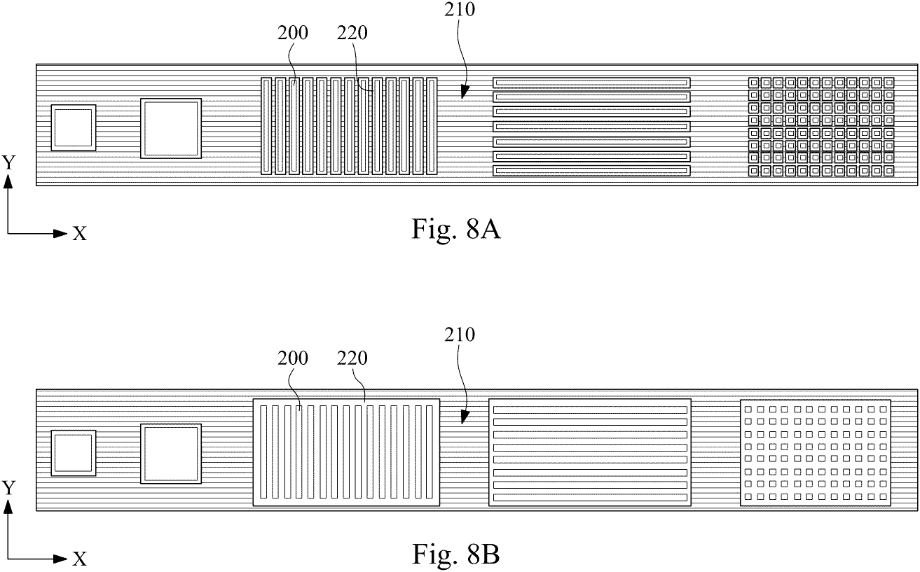

As shown in FIGS. 3A-3C, 5A-5E and 6A-6E, the SRAF patterns 210 are connected to the TIS alignment mark pattern 200, thereby forming a continuous groove pattern. In other embodiments, the SRAF pattern 210 are separated from the TIS alignment marks 200 as shown in FIGS. 8A and 8B.

In some embodiments, as shown in FIG. 8A, each of the patterns of the TIS alignment marks 200 is surrounded by a margin area 220, which corresponds to the absorber layer in the case of the structure shown in FIGS. 5A-5E and to the opening exposing the substrate in the case of the structure shown in FIGS. 6F-6I. The width of the margin area 200 (a distance between the alignment mark pattern 200 and the SRAF pattern 210) is in a range from about 20 nm to 200 nm on the photo mask in some embodiments.

In other embodiments, as shown in FIG. 8B, the entire alignment marks (a group of the line-and-space patterns) are surrounded by the margin area 220. The distance between the alignment mark pattern 200 and the SRAF pattern 210 is in a range from about 20 nm to 200 nm on the photo mask in some embodiments.

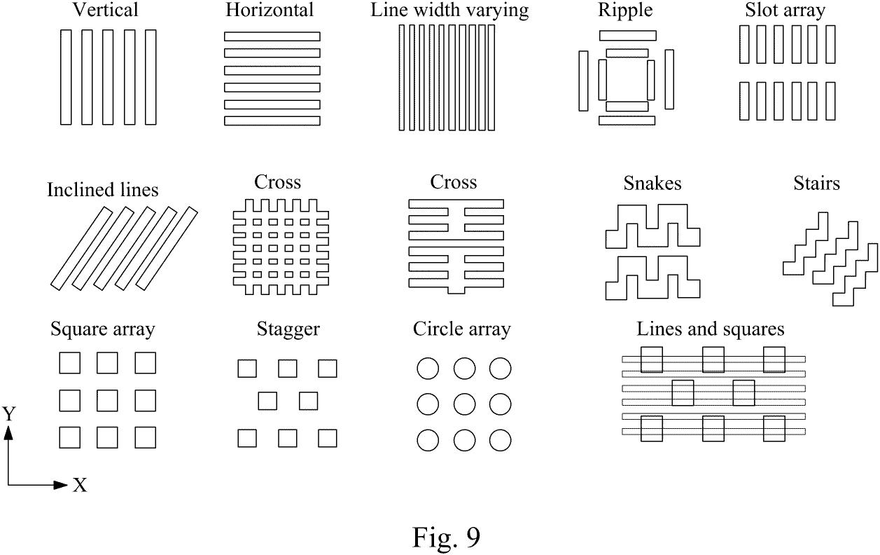

FIG. 9 shows various patterns for the SRAF according to embodiments of the present disclosure. In FIG. 9, the dark patterns correspond to reflective patterns (no absorber) and the background corresponds to the absorber layer (or substrate).

In some embodiments, the SRAF patterns are grating patterns. In some embodiments, the SRAF patterns are simple line-and-space patterns with a constant pitch extending in the X direction (horizontal) or the Y direction (vertical). In other embodiments, the pitch varies. In some embodiments, the pitch decreases as the distance to the TIS alignment pattern decreases. In other embodiments, the pitch increases as the distance to the TIS alignment pattern increases. In some embodiments, the pitch randomly changes. When the pitch randomly changes, the average pitch thereof is equal to or more than about 40 nm and less than about 160 nm.

In some embodiments, line width of the line patterns varies. In some embodiments, the width decreases as the distance to the TIS alignment pattern decreases. In other embodiments, the width increases as the distance to the TIS alignment pattern increases. In some embodiments, the width randomly changes. When the width randomly changes, the average width thereof is in a range from about 10 nm to about 50 nm.

In some embodiments, the line patterns of the SRAF patterns are segmented (cut into pieces) as a slot array.

In some embodiments, the SRAF patterns include a combination of the vertical patterns and the horizontal patterns.

In some embodiments, the line patterns of the SRAF are inclined with respect to the X or Y direction (pattern extending direction of the TIS alignment marks). In some embodiments, the inclination angle with respect to the X or Y direction is about 10 degrees to about 80 degrees.

In some embodiments, the SRAF patterns include ripple patterns which include vertical patterns arranged in parallel with longitudinal sides of vertically or horizontally extending alignment mark and horizontal patterns arranged in parallel with the latitudinal sides thereof.

In some embodiments, the SRAF patterns include an array or matrix of square or circular patterns. In some embodiments, the matrix is a regular matrix and in other embodiments, the matrix is a staggered matrix. The pitches in the X direction and/or the Y direction are constant in some embodiments and varies in other embodiments similar to the line patterns as set forth above.

In some embodiments, the SRAF patterns include zig-zag patterns such as a snake pattern, a crank pattern, and a stair pattern.

In some embodiments, the SRAF patterns include any combination of the aforementioned patterns.

In some embodiments, the SRAF patterns as a layout pattern (e.g., patterns as GDS layout data) overlaps the alignment mark patterns as a layout pattern. In other embodiments, the SRAF layout patterns do not to overlap the alignment mark layout patterns. In some embodiments, the mask drawing data is the combination, for example, the logical OR, of the SRAF layout pattern and the alignment mark layout pattern.

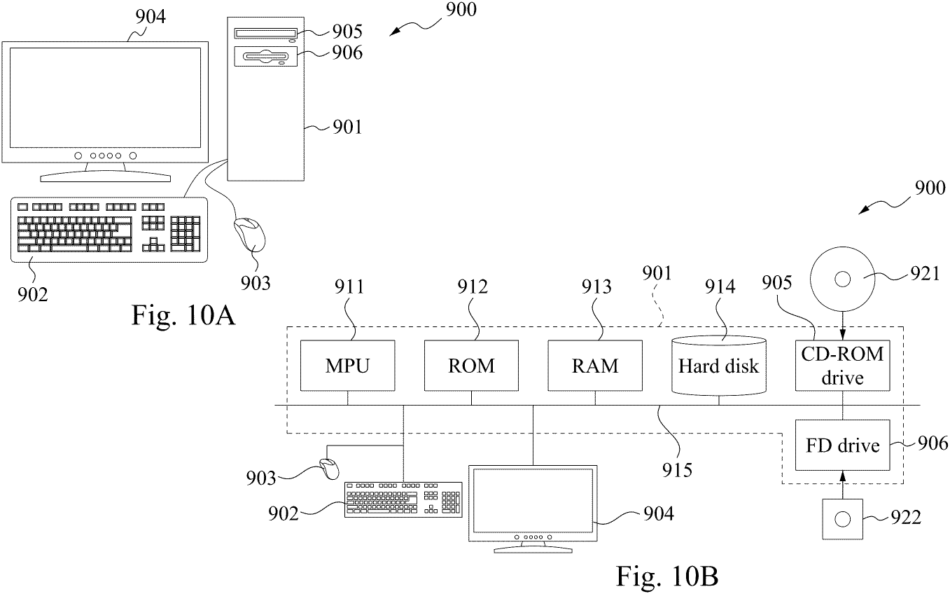

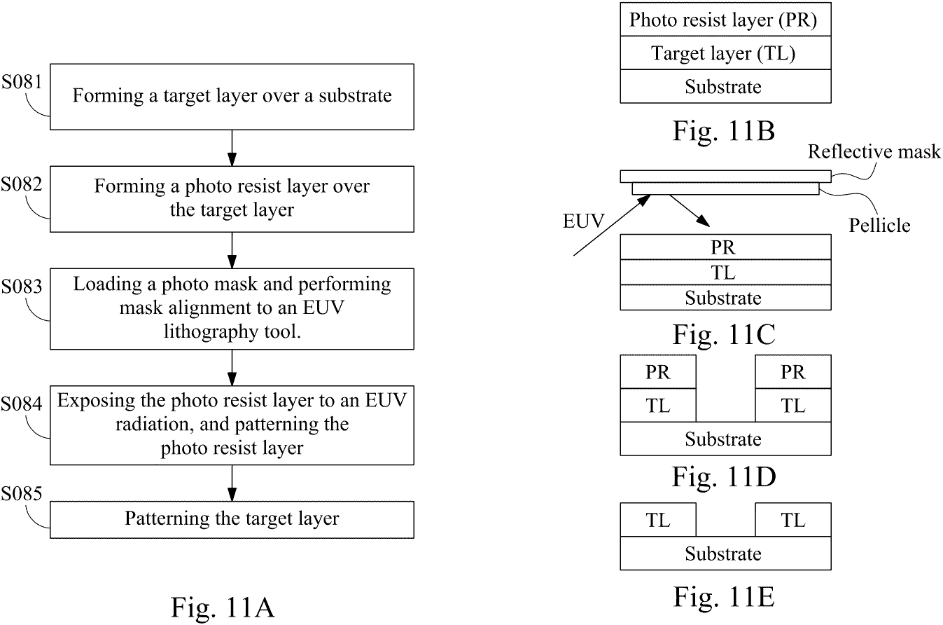

The SRAF patterns are generated by a photo mask data generating apparatus shown in FIGS. 10A and 10B. FIG. 10A is a schematic view of a computer system that executes the photo mask data generating process according to one or more embodiments as described above. All of or a part of the process, method and/or operations of the foregoing embodiments can be realized using computer hardware and computer programs executed thereon. In FIG. 10A, a computer system 900 is provided with a computer 901 including an optical disk read only memory (e.g., CD-ROM or DVD-ROM) drive 905 and a magnetic disk drive 906, a keyboard 902, a mouse 903, and a monitor 904.

FIG. 10B is a diagram showing an internal configuration of the computer system 900. In FIG. 10B, the computer 901 is provided with, in addition to the optical disk drive 905 and the magnetic disk drive 906, one or more processors 911, such as a micro processing unit (MPU), a ROM 912 in which a program such as a boot up program is stored, a random access memory (RAM) 913 that is connected to the MPU 911 and in which a command of an application program is temporarily stored and a temporary storage area is provided, a hard disk 914 in which an application program, a system program, and data are stored, and a bus 915 that connects the MPU 911, the ROM 912, and the like. Note that the computer 901 may include a network card (not shown) for providing a connection to a LAN.

The program for causing the computer system 900 to execute the functions of the photo mask data generating apparatus in the foregoing embodiments may be stored in an optical disk 921 or a magnetic disk 922, which are inserted into the optical disk drive 905 or the magnetic disk drive 906, and transmitted to the hard disk 914. Alternatively, the program may be transmitted via a network (not shown) to the computer 901 and stored in the hard disk 914. At the time of execution, the program is loaded into the RAM 913. The program may be loaded from the optical disk 921 or the magnetic disk 922, or directly from a network.

The program does not necessarily have to include, for example, an operating system (OS) or a third party program to cause the computer 901 to execute the functions of the photo mask data generating apparatus in the foregoing embodiments. The program may only include a command portion to call an appropriate function (module) in a controlled mode and obtain desired results.

In the programs, the functions realized by the programs do not include functions that can be realized only by hardware in some embodiments. For example, functions that can be realized only by hardware, such as a network interface, in an acquiring unit that acquires information or an output unit that outputs information are not included in the functions realized by the above-described programs in some embodiments. Furthermore, a computer that executes the programs may be a single computer or may be multiple computers.

Further, the entirety of or a part of the programs to realize the functions of the photo mask data generating apparatus is a part of another program used for photo mask fabrication processes in some embodiments. In addition, the entirety of or a part of the programs to realize the functions of the photo mask data generating apparatus is realized by a ROM made of, for example, a semiconductor device in some embodiments.

FIG. 11A shows a flowchart of a method of making a semiconductor device, and FIGS. 11B, 11C, 11D and 11E show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 11A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802, of FIG. 11A, a photo resist layer is formed over the target layer, as shown in FIG. 11B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer.

At S803 of FIG. 11A, an EUV photo mask as explained above is loaded into an EUV lithography tool (e.g., EUV scanner) and a mask alignment operation is performed using a TIS alignment system.

At S804 of FIG. 11A, the photo resist layer is patterned using the EUV photo mask, as shown in FIG. 11B. During the exposing process, the integrated circuit (IC) design pattern defined on the EUV mask is imaged to the photo resist layer to form a latent pattern thereon. The patterning of the photo resist layer further includes developing the exposed photo resist layer to form a patterned photo resist layer having one or more openings. In one embodiment where the photo resist layer is a positive tone photo resist layer, the exposed portions of the photo resist layer are removed during the developing process. The patterning of the photo resist layer may further include other process steps, such as various baking steps at different stages. For example, a post-exposure-baking (PEB) process may be implemented after the photolithography exposing process and before the developing process.

At S805 of FIG. 11A, the target layer is patterned utilizing the patterned photo resist layer as an etching mask, as shown in FIG. 11D. In some embodiments, the patterning the target layer includes applying an etching process to the target layer using the patterned photo resist layer as an etch mask. The portions of the target layer exposed within the openings of the patterned photo resist layer are etched while the remaining portions are protected from etching. Further, the patterned photo resist layer may be removed by wet stripping or plasma ashing, as shown in FIG. 11E.

In the present disclosure, the SRAF patterns are provided over or around the TIS alignment marks of an EUV photo mask, which can suppress the background signal (e.g., undesired EUV reflection). Thus, it is possible to increase a signal contrast (e.g., S/N ratio), and to improve alignment accuracy of the EUV photo mask to the EUV lithography tool.

It will be understood that not all advantages have been necessarily discussed herein, no particular advantage is required for all embodiments or examples, and other embodiments or examples may offer different advantages.

According to one aspect of the present application, a photo mask for an extreme ultraviolet (EUV) lithography includes a mask alignment mark for aligning the photo mask to an EUV lithography tool, and sub-resolution assist patterns disposed around the mask alignment mark. A dimension of the sub-resolution assist patterns is in a range from 10 nm to 50 nm. In one or more of the foregoing and following embodiments, the sub-resolution assist patterns include periodic patterns having a pitch equal to or more than 40 nm and less than 160 nm. In one or more of the foregoing and following embodiments, the sub-resolution assist patterns include periodic line patterns having a width in a range from 10 nm to 50 nm and a pitch equal to or more than 40 nm and less than 160 nm. In one or more of the foregoing and following embodiments, the periodic line patterns of the sub-resolution assist patterns are grooves, trenches or openings formed in an absorber layer. In one or more of the foregoing and following embodiments, the mask alignment mark includes periodic line patterns having a width greater than the width of the periodic line patterns of the sub-resolution assist patterns. In one or more of the foregoing and following embodiments, the periodic line patterns of the mask alignment mark extend in a first direction and arranged in parallel with each other in a second direction crossing the first direction, and the periodic line patterns of the sub-resolution assist patterns extend in the first direction and arranged in parallel with each other in the second direction. In one or more of the foregoing and following embodiments, the periodic line patterns of the mask alignment mark extend in a first direction and arranged in parallel with each other in a second direction crossing the first direction, and the periodic line patterns of the sub-resolution assist patterns extend in the second direction and arranged in parallel with each other in the first direction. In one or more of the foregoing and following embodiments, the periodic line patterns of the mask alignment mark are grooves, trenches or openings formed in an absorber layer, and the periodic line patterns of the sub-resolution assist patterns are connected to at least one of the periodic line patterns of the mask alignment mark.

In accordance another aspect of the present disclosure, a photo mask for an extreme ultraviolet (EUV) lithography includes a substrate, a reflective multilayer structure disposed over the substrate, a capping layer disposed over the reflective multilayer structure, and an absorber layer disposed over the capping layer. The absorber layer has a refractive index equal to or less than 0.95 and an absorption coefficient k equal to or less than 0.04 for an EUV light. The photo mask includes a mask alignment mark for aligning the photo mask to an EUV lithography tool, and a background intensity suppression pattern disposed around the mask alignment mark having a dimension smaller than a pattern included in the mask alignment mark. In one or more of the foregoing and following embodiments, the background intensity suppression pattern comprises grating patterns. In one or more of the foregoing and following embodiments, the mask alignment mark includes periodic line patterns, and the background intensity suppression pattern is disposed at least an area between adjacent two line patterns of the mask alignment mark. In one or more of the foregoing and following embodiments, the grating patterns include periodic line patterns having a width in a range from 10 nm to 50 nm and a pitch equal to or more than 40 nm and less than 160 nm, and the periodic line patterns of the mask alignment mark have a pitch in a range from 3000 nm to 5000 nm and a line width in a range from 100 nm to 300 nm. In one or more of the foregoing and following embodiments, the periodic line patterns of the grating and the mask alignment mark are grooves, trenches or openings formed in the absorber layer. In one or more of the foregoing and following embodiments, the periodic line patterns of the grating and the mask alignment mark are formed of the reflective multilayer surrounded by an opening at a bottom of which the substrate is exposed. In one or more of the foregoing and following embodiments, the grating patterns are non-periodic. In one or more of the foregoing and following embodiments, a reflectivity of the absorber layer is equal to or greater than 5%.

In accordance with another aspect of the present disclosure, a photo mask for an extreme ultraviolet (EUV) lithography includes a circuit pattern area in which circuit patterns are disposed, a black border pattern surrounding the circuit pattern area, and a mask alignment mark area disposed outside the black border pattern. The mask alignment mark area includes a coarse alignment mark and a fine alignment mark, and sub-resolution assist patterns disposed in the mask alignment mark area. In one or more of the foregoing and following embodiments, the photo mask includes a substrate, a reflective multilayer structure disposed over the substrate, a capping layer disposed over the reflective multilayer structure, and an absorber layer disposed over the capping layer. The coarse alignment mark is a square pattern in plan view, on which no absorber layer is disposed, and the coarse alignment mark is surrounded by an opening exposing the substrate and the opening is surrounded by an area where the absorber layer is disposed. In one or more of the foregoing and following embodiments, the coarse alignment mark includes the capping layer. In one or more of the foregoing and following embodiments, the sub-resolution assist patterns include patterns having a pitch equal to or more than 40 nm and less than 160 nm.

In accordance with another aspect of the present disclosure, in a method of manufacturing a photo mask for an extreme ultraviolet (EUV) lithography, a mask blank is provided. The mask blank includes a substrate, a reflective multilayer structure disposed over the substrate, a capping layer disposed over the reflective multilayer structure, a first layer disposed over the capping layer, an absorber layer disposed over the first layer, and a second layer disposed over the absorber layer. The second layer and the absorber layer are patterned, the first layer, the capping layer and the reflective multilayer structure are patterned to form a pattern, and the absorber layer and the first layer are removed from the pattern. In one or more of the foregoing and following embodiments, the first and second layers are made of tantalum oxide. In one or more of the foregoing and following embodiments, the absorber layer has a refractive index equal to or less than 0.95 and an absorption coefficient k equal to or less than 0.04 for an EUV light.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photo mask for extreme ultraviolet (EUV) lithography, the photo mask comprising:
a mask alignment mark for aligning the photo mask to an EUV lithography tool; and
sub-resolution assist patterns disposed around the mask alignment mark,
wherein a dimension of the sub-resolution assist patterns is in a range from 10 nm to 50 nm.

2. The photo mask of claim 1, wherein the sub-resolution assist patterns include periodic patterns having a pitch equal to or more than 40 nm and less than 160 nm.

3. The photo mask of claim 1, wherein the sub-resolution assist patterns include periodic line patterns having a width in a range from 10 nm to 50 nm and a pitch equal to or more than 40 nm and less than 160 nm.

4. The photo mask of claim 3, wherein the periodic line patterns of the sub-resolution assist patterns are grooves, trenches or openings formed in an absorber layer.

5. The photo mask of claim 4, wherein the mask alignment mark includes periodic line patterns having a width greater than the width of the periodic line patterns of the sub-resolution assist patterns.

6. The photo mask of claim 5, wherein:
the periodic line patterns of the mask alignment mark extend in a first direction and are arranged in parallel with each other in a second direction crossing the first direction, and
the periodic line patterns of the sub-resolution assist patterns extend in the first direction and are arranged in parallel with each other in the second direction.

7. The photo mask of claim 5, wherein:
the periodic line patterns of the mask alignment mark extend in a first direction and are arranged in parallel with each other in a second direction crossing the first direction, and
the periodic line patterns of the sub-resolution assist patterns extend in the second direction and are arranged in parallel with each other in the first direction.

8. The photo mask of claim 5, wherein:
the periodic line patterns of the mask alignment mark are grooves, trenches or openings formed in an absorber layer, and
the periodic line patterns of the sub-resolution assist patterns are connected to at least one of the periodic line patterns of the mask alignment mark.

9. A photo mask for extreme ultraviolet (EUV) lithography, the photo mask comprising:
a substrate;
a reflective multilayer structure disposed over the substrate;
a capping layer disposed over the reflective multilayer structure; and
an absorber layer disposed over the capping layer, wherein:
the absorber layer has a refractive index equal to or less than 0.95 and an absorption coefficient k equal to or less than 0.04 for an EUV light, and
the photo mask includes:
a mask alignment mark for aligning the photo mask to an EUV lithography tool; and
a background intensity suppression pattern disposed around the mask alignment mark having a dimension smaller than a pattern included in the mask alignment mark.

10. The photo mask of claim 9, wherein the background intensity suppression pattern comprises grating patterns.

11. The photo mask of claim 10, wherein the mask alignment mark includes periodic line patterns, and the background intensity suppression pattern is disposed at least an area between adjacent two line patterns of the mask alignment mark.

12. The photo mask of claim 11, wherein:
the grating patterns include periodic line patterns having a width in a range from 10 nm to 50 nm and a pitch equal to or more than 40 nm and less than 160 nm, and
the periodic line patterns of the mask alignment mark have a pitch in a range from 3000 nm to 5000 nm and a line width in a range from 100 nm to 300 nm.

13. The photo mask of claim 12, wherein the periodic line patterns of the grating and the mask alignment mark are grooves, trenches or openings formed in the absorber layer.

14. The photo mask of claim 12, wherein the periodic line patterns of the grating and the mask alignment mark are formed of the reflective multilayer surrounded by an opening at a bottom of which the substrate is exposed.

15. The photo mask of claim 10, wherein the grating patterns are non-periodic.

16. The photo mask of claim 9, wherein a reflectivity of the absorber layer is equal to or greater than 5%.

17. A photo mask for extreme ultraviolet (EUV) lithography, the photo mask comprising:
a circuit pattern area in which circuit patterns are disposed;
a black border pattern surrounding the circuit pattern area; and
a mask alignment mark area disposed outside the black border pattern,
wherein the mask alignment mark area includes:
a coarse alignment mark and a fine alignment mark, and
sub-resolution assist patterns disposed in the mask alignment mark area.

18. The photo mask of claim 17, wherein:
the photo mask includes:
a substrate;
a reflective multilayer structure disposed over the substrate;
a capping layer disposed over the reflective multilayer structure; and
an absorber layer disposed over the capping layer,
the coarse alignment mark is a square pattern in plan view, on which no absorber layer is disposed, and
the coarse alignment mark is surrounded by an opening exposing the substrate and the opening is surrounded by an area where the absorber layer is disposed.

19. The photo mask of claim 18, wherein the coarse alignment mark includes the capping layer.

20. The photo mask of claim 18, wherein the sub-resolution assist patterns include patterns having a pitch equal to or more than 40 nm and less than 160 nm.
